(19) United States
(12) Patent Application Publication
(10) Pub. No.: US 2025/0112109 A1
(43) Pub. Date: Apr. 3, 2025

(54) Semiconductor Package and Method for Manufacturing Semiconductor Package

(71) Applicant: Huawei Digital Power Technologies Co., Ltd., Shenzhen (CN)

(72) Inventors: Mirko Bernardoni, Munich (DE); Gilberto Curatola, Nuremberg (DE)

(21) Appl. No.: 18/980,586

(22) Filed: Dec. 13, 2024

Related U.S. Application Data
(63) Continuation of application No. PCT/EP2022/066255, filed on Jun. 15, 2022.

(51) Int. Cl. H01L 23/367; H01L 21/48; H01L 23/00; H01L 23/373; H01L 25/07

(52) U.S. Cl. CPC H01L 23/3672; H01L 21/4875; H01L 23/3735; H01L 23/3736; H01L 25/072; H01L 24/40; H01L 2224/40137; H01L 2224/40245; H01L 2924/13055

(57) ABSTRACT

A semiconductor package comprises: a thermally conductive layer and semiconductor devices thermally connected with the thermally conductive layer. The semiconductor devices produce heat, which the thermally conductive layer dissipates at least partly. Some heat is transferred from a semiconductor device to another semiconductor device. The semiconductor package further comprises a temperature balancing element arranged in thermal connection i) with the thermally conductive layer and ii) with the other semiconductor device(s).

### CROSS-REFERENCE TO RELATED APPLICATIONS

This is a continuation of Int'l Patent App. No. PCT/EP2022/066255, filed on Jun. 15, 2022, which is incorporated by reference.

### FIELD

The present disclosure is related to the field of semiconductor devices and packaging. In this field, the disclosure is concerned with heat dissipation in a semiconductor package. The disclosure proposes a semiconductor package that includes at least two semiconductor devices and a thermally conductive layer. Further, the present disclosure relates to a method for manufacturing such a semiconductor package.

### BACKGROUND

A semiconductor package can comprise two or more semiconductor devices. A semiconductor device produces heat when it is operated, for instance, when it is supplied with electricity to fulfil its functions.

In the semiconductor package, the semiconductor devices, which can for example be arranged in a row, exchange heat when being operated. The semiconductor devices are arranged in thermal connection with a thermally conductive layer, which can dissipate some of the heat away.

However, one of the semiconductor devices can receive more heat from the neighboring semiconductor devices than the neighboring semiconductor devices do, due to the design of the semiconductor package. When one semiconductor device is working at a higher temperature than its neighbors, the distribution of current is uneven among the semiconductor devices, which can in turn lower the efficiency of the semiconductor device and reduce the long-term reliability and the service life of the semiconductor package.

If the hotter semiconductor device becomes more electrically conductive, the hotter semiconductor device might conduct more current, which could trigger a thermal runaway and lead to a failure. This can for example be the case when the semiconductor package is a power module, which includes insulated-gate bipolar transistors (IGBTs) operating with negative temperature coefficients.

### SUMMARY

In view of the above, the present disclosure aims to provide ways of improving the balance of heat among semiconductor devices in a semiconductor package. Objectives of the present disclosure include to design and manufacture a semiconductor package, which enhances the long-term reliability of the semiconductor package.

These and other objectives are achieved by the solution of this disclosure as described in the independent claims. Advantageous implementations are further defined in the dependent claims.

A first aspect of this disclosure provides a semiconductor package, for example a power module, comprising: a thermally conductive layer; and at least two semiconductor devices arranged in thermal connection with the thermally conductive layer; wherein the at least two semiconductor devices produce heat when being operated; wherein the thermally conductive layer is configured to dissipate at least a part of said heat; some of said heat being transferred at least from one of the at least two semiconductor devices to another one of the at least two semiconductor devices; and wherein the semiconductor package further comprises at least one temperature balancing element, the at least one temperature balancing element being arranged in thermal connection i) with the thermally conductive layer and ii) with at least one of the at least two semiconductor devices so as to reduce a temperature gradient between the at least two semiconductor devices.

Heat may be transferred between two semiconductor devices that are arranged near one another, hence neighboring or adjacent or in vicinity to each other, in the semiconductor package. As the temperature balancing element is thermally connected with the thermally conductive layer as well as a semiconductor device(s), either directly or indirectly, e.g., via zero, one or more thermally conductive materials, a non-negligible quantity of heat may flow between these components thusly coupled.

In various implementations, the thermally conductive layer may be thermally connected with a heat sink. For example, the thermally conductive layer may be mounted on the heat sink, either directly or indirectly i) via a thermally insulating material providing electrical insulation, ii) via another thermally conductive material, or iii) via a stack comprising both thermally conductive and thermally insulating materials.

In various implementations, the at least two semiconductor devices may be supplied with currents in parallel.

In various implementations, the at least one temperature balancing element may be arranged in contact i) with the thermally conductive layer and/or ii) with at least one of the at least two semiconductor devices, for example with all of these semiconductor devices.

In an implementation form of the first aspect, the at least one temperature balancing element may be arranged to locally decrease the thickness of the thermally conductive layer.

For example, the at least one temperature balancing element may be accommodated or embedded within the overall shape of the thermally conductive layer. As the at least one temperature balancing element does not protrude out of the thermally conductive layer, the compactness of the semiconductor package can be enhanced.

In an implementation form of the first aspect, the at least one temperature balancing element may be configured to locally decrease the thickness of the thermally conductive layer by 5% to 100%, for example by 20% to 90% or by 40% to 80%.

The thickness may for example be decreased by etching the thermally conductive layer when manufacturing the semiconductor package. Advantageously, the decrease in thickness may not or not substantially interfere with the electrical properties of the semiconductor device. The semiconductor package may show neither an increase in electrical resistance nor an increase in parasitic inductance in the branches having the semiconductor devices that are close to the thermal balancing element.

In an implementation form of the first aspect, the at least one temperature balancing element may include a thermal insulator, the thermal insulator having a lower thermal conductivity than the thermally conductive layer.

When this implementation form is in operation, the thermal insulator can for example increase the thermal resistance near a colder semiconductor device, so as to increase the average or peak temperature thereof and bring it closer to the average or peak temperature of the hottest semiconductor device. As temperature gradients between the semiconductor devices are reduced, the balance of heat can be improved in a semiconductor package.

As an example of this implementation form, the thermal insulator may be made out of a thermally insulating substance, which is selected from the group comprising: air, non-conductive polymers, and insulating packaging materials.

In various implementations, the thermal insulator may have a thermal conductivity of less than 50 watts per meter-kelvin (W/mK), or of less than 10 W/mK, or of less than 1 W/mK, while the thermally conductive layer may have a thermal conductivity of more than 100 or 200 W/mK.

In an implementation form of the first aspect, the thermal insulator may be arranged in a peripheral region surrounding said at least two semiconductor devices.

For example, a region extending between said at least two neighboring semiconductor devices may be free of thermal insulator and occupied by the thermally conductive layer. The thermal insulator may be arranged at least on one side of one of the two semiconductor devices.

In an implementation form of the first aspect, the at least one temperature balancing element may include a thermal conductor made of thermally conductive material which has a higher thermal conductivity than the thermally conductive layer, and the thermal conductor may be arranged between said at least two semiconductor devices.

The thermal conductor being arranged “between” two semiconductor devices can be read as meaning that a main heat flow path leading from a semiconductor device to another semiconductor device shall pass through or near the thermal conductor.

When this implementation form is in operation, the temperature balancing element can for example decrease the thermal resistance between the hottest semiconductor device and a neighboring, colder semiconductor device, so as to enhance heat transfer from the hottest semiconductor device toward the colder semiconductor device. As temperature gradients between the semiconductor devices are reduced, the balance of heat can be improved in a semiconductor package.

In an implementation form of the first aspect, the thermal conductor may be made out of gold, gold alloy, copper, or copper alloy, and the thermally conductive layer is made out of aluminum, aluminum alloy, copper or copper alloy.

In various forms, the thermal conductor may have a thermal conductivity of more than 200 W/mK, or of more than 300 W/mK, or of more than 400 W/mK.

In an implementation form of the first aspect, the thermal conductor may include a thermal interface arranged between the thermally conductive layer and one of the at least two semiconductor devices, the thermal interface optionally extends over the whole area underlying said one semiconductor device.

In the optional implementation, the thermal interface can represent an additional thermally conducting layer under said one semiconductor device. The thermal interface may further extend beyond the whole area underlying said one semiconductor device.

Advantageously, the thermal interface may be formed by a local increase of the thickness of the thermally conductive layer.

When this implementation form is in operation, the temperature balancing element can for example largely decrease the thermal resistance between the hottest semiconductor device and a neighboring, colder semiconductor device, so as to enhance heat transfer from the hottest semiconductor device toward the colder semiconductor device.

In an implementation form of the first aspect, the thermal interface may be made out of the same material as the thermally conductive layer, and the thermal interface is optionally integral or one-piece with the thermally conductive layer.

This configuration can simplify the manufacturing of the semiconductor package.

In an implementation form of the first aspect, the thermal interface may be configured to locally increase the thickness of the thermally conductive layer by 30% to 200%, or by 50% to 100%.

In various implementations, the thermally conductive layer may be made out of aluminum, aluminum alloy, copper, or copper alloy. In various implementations, the thermally conductive layer may be monolithic, for example, the thermally conductive layer may be formed of one sole layer. In various implementations, the thermally conductive layer may be a direct-bonded copper (DBC) substrate.

In an implementation form of the first aspect, the thermally conductive layer may have a substantially constant thickness at least in a region encompassing the at least two semiconductor devices.

In various implementations, the thickness of the thermally conductive layer may be comprised between 0.1 millimeters (mm) and 1 mm.

In an implementation form of the first aspect, the thermally conductive layer may have a thermal conductivity of more than 100 W/mK, or of more than 200 W/mK, or of more than 300 W/mK.

In various implementations, a distance separating the at least one temperature balancing element from the closest one of the at least two semiconductor devices may be smaller than 300%, or smaller than 100%, or smaller than 50%, or smaller than 25%, of the largest dimension of the closest one of the at least two semiconductor devices.

The smaller this separating distance is, the larger the influence of the at least one temperature balancing element on the local thermal resistance may be, hence the larger its effect on the temperature gradients between the at least two semiconductor devices may be.

The largest dimension of the closest one of the at least two semiconductor devices may be selected as the length of a diagonal of the semiconductor device in case the semiconductor device substantially has a rectangular shape.

In various implementations, the distance separating the at least one temperature balancing element from the closest one of the at least two semiconductor devices may be smaller than 2 mm, for instance smaller than 1 mm or smaller than 0.5 mm. Such a separating distance may enable the at least one temperature balancing element to more efficiently influence the local thermal resistance.

In various implementations, the semiconductor package may comprise more than two semiconductor devices, wherein a distance separating two neighboring semiconductor devices may be larger than a distance separating two other neighboring semiconductor devices. Such different separating distances may provide for a large thermal interaction between closer semiconductor devices and a small thermal interaction between more distant semiconductor devices.

In an implementation form of the first aspect, the at least one temperature balancing element may extend i) on at least one side of the closest one of the at least two semiconductor devices and ii) along 50% to 150%, or along 50% to 100% of the length of said at least one side.

Such extension of the at least one temperature balancing element enables it to influence the thermal resistance along all or part of this side.

In an implementation form of the first aspect, the at least one temperature balancing element may extend i) on at least two sides of the closest one of the at least two semiconductor devices and ii) along 50% to 150%, or along 50% to 100% of the respective length of said at least two sides, and the at least one temperature balancing element optionally has substantially a shape selected from the group comprising: a segment of a polygon, a segment of rectangle, an L-shape, an arc of a circle, and an arc of an ellipse.

Such extension of the at least one temperature balancing element enables it to influence largely the thermal resistance along all or part of these two sides.

In various implementations, the at least one temperature balancing element may extend around about 15% to about 75% of the perimeter of the closest semiconductor device.

In an implementation form of the first aspect, an outer face of the thermally conductive layer may comprise an extended region free of semiconductor devices.

Such an extended region allows the thermally conductive layer to dissipate a relatively large quantity of heat when the at least two semiconductor devices are being operated.

The extended region may for example extend from a semiconductor device up to an edge of the thermally conductive layer.

In an implementation form of the first aspect, the semiconductor package may have at least two temperature balancing elements, the temperature balancing elements being optionally arranged in a group of nearby temperature balancing elements.

Two such nearby temperature balancing elements of a group may be separated by less than 300 μm.

In an implementation form of the first aspect, said at least two semiconductor devices may be arranged in an array, and optionally, said at least two semiconductor devices include at least three semiconductor devices.

An array of semiconductor devices may simplify the manufacturing of the semiconductor package.

In an implementation example, the array may have one row and two columns, hence two semiconductor devices in total. In other implementation examples, the array may have more than one row and/or more than two columns. For example, the array may have 2 rows by 3 columns.

In an implementation form of the first aspect, the semiconductor package may be a power module, the at least two semiconductor devices including for example IGBTs, and optionally, the at least two semiconductor devices may be embedded in an electrically insulating layer.

In various implementations, the at least two semiconductor devices may include a chip, for example, an embedded chip.

A second aspect of this disclosure provides a method for manufacturing a semiconductor package, the method comprising: providing a thermally conductive layer, providing at least two semiconductor devices, arranging said at least two semiconductor devices in thermal connection with the thermally conductive layer, the at least two semiconductor devices producing heat when being operated; wherein the thermally conductive layer is configured to dissipate at least a part of the heat produced by the at least two semiconductor devices; wherein some of said heat being transferred at least from one of the at least two semiconductor devices to another one of the at least two semiconductor devices; and wherein the semiconductor package has at least one temperature balancing element, the at least one temperature balancing element being arranged in thermal connection i) with the thermally conductive layer and ii) with at least one of the at least two semiconductor devices so as to reduce a temperature gradient between two neighboring semiconductor devices of the at least two semiconductor devices.

The method of the second aspect makes it possible to manufacture a semiconductor package in accordance with the first aspect described above. The method of the second aspect accordingly achieves all the advantages described above for the first aspect.

The method of the second aspect may comprise further implementation forms, which correspond to the implementation forms of the semiconductor package of the first aspect. The implementation forms of the method may be such that the semiconductor package according to the implementation forms of the first aspect is manufactured.

### BRIEF DESCRIPTION OF THE DRAWINGS

The above-described aspects and implementation forms will be explained in the following description of specific, exemplary embodiments of the present disclosure in relation to the enclosed drawings.

FIG. 1 shows a schematic top view of a part of a semiconductor package;

FIG. 2 is a schematic isotherm map showing temperatures (in degrees Celsius) on areas of the semiconductor devices of the semiconductor package of FIG. 1 from atop;

FIG. 3 shows a schematic top view of a part of a semiconductor package according to a first embodiment;

FIG. 4 shows a schematic enlarged top view of detail IV in FIG. 3;

FIG. 5 shows a schematic cross-section along line V-V in FIG. 3;

FIG. 6 is a schematic cross-section along direction Y shown in FIG. 4;

FIG. 7 is a schematic diagram plotting temperatures (in degrees Celsius) as a function of a position (in mm) along direction Y shown in FIG. 3, in semiconductor devices of various semiconductor packages, for example the one of FIGS. 3 to 6;

FIGS. 8-10 are schematic top perspective views, similar to FIG. 3, of parts of semiconductor packages according to various embodiments;

FIGS. 11-19 are schematic cross-sections, similar to FIG. 6, through semiconductor packages according to various embodiments; and

FIG. 20 illustrates a method according to another embodiment of the present disclosure for manufacturing a semiconductor package according to this disclosure.

### DETAILED DESCRIPTION

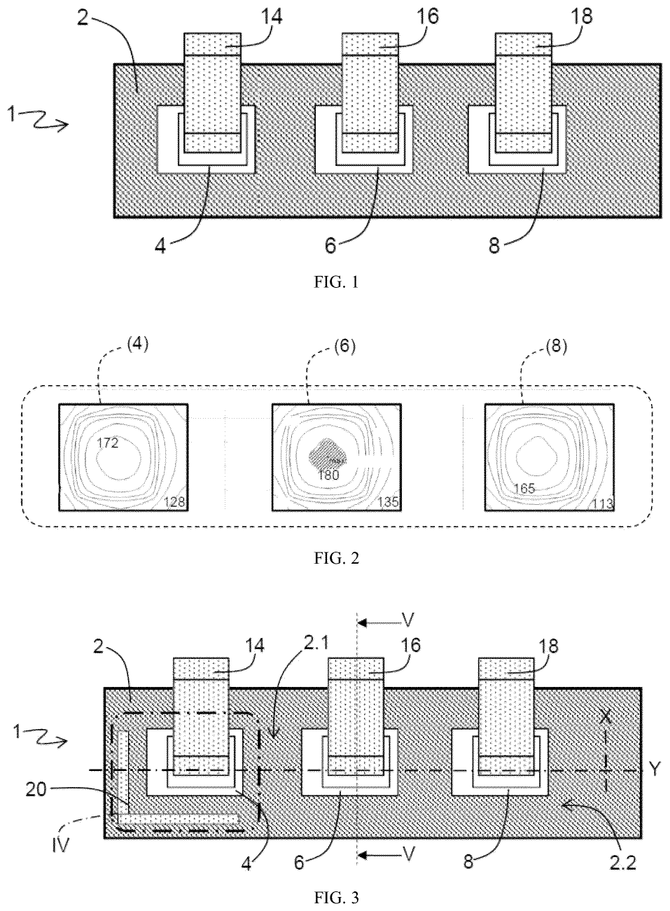

FIG. 1 shows a part of a semiconductor package 1 comprising a thermally conductive layer 2 and three semiconductor devices 4, 6 and 8. The semiconductor devices 4, 6 and 8 produce heat when they are being operated, for example, supplied with electrical current.

The semiconductor devices 4, 6 and 8 are arranged in thermal connection with the thermally conductive layer 2. The thermally conductive layer 2 is configured to dissipate at least a part of the heat produced by the semiconductor devices 4, 6 and 8. Some of this heat is being transferred between the semiconductor devices 4, 6 and 8 in operation. This heat transfer often occurs via the thermally conductive layer 2 and from the hotter one(s) of the semiconductor devices 4, 6, 8 to the colder one(s) of the semiconductor devices 4, 6, 8. Usually, the closer the semiconductor devices 4, 6, 8 are, the more heat is transferred from one semiconductor device to another.

In the example of FIG. 1 the central semiconductor device 6 is the hottest, while the lateral semiconductor devices 4 and 8 are colder, as illustrated on the isotherm map of FIG. 2 where the figures represent temperatures in degrees Celsius. The hottest area (center) mapped for the central semiconductor device 6 may reach a temperature of about 180° C. with a central peak at 183.5° C., while the hottest areas (centers) mapped for the lateral semiconductor devices 4 and 8 can reach about 172° C.

Some heat produced by the lateral semiconductor devices 4 and 8 may be transferred to the central semiconductor device 6, while a significant part of the heat produced by the lateral semiconductor devices 4 and 8 can flow away toward the edges of the thermally conductive layer 2. The thermally conductive layer 2 can present a higher thermal resistance, hence smaller heat flows, near the central semiconductor device 6 than beyond the lateral semiconductor devices 4 and 8.

FIGS. 3 to 6 show a part of a semiconductor package 1 according to a first embodiment. The semiconductor package 1 of FIGS. 3 to 6 comprises a thermally conductive layer 2 and three semiconductor devices 4, 6 and 8 arranged in thermal connection with the thermally conductive layer 2. The semiconductor package 1 may be a power module and form a system in package (SIP). The semiconductor devices 4, 6 and 8 may be embedded in a not-shown electrically insulating layer. The semiconductor device(s) 4, 6 and/or 8 may include IGBTs.

The semiconductor devices 4, 6 and 8 may be arranged in an array having one row and three columns. The semiconductor package 1 of FIGS. 3 to 6 may further comprise clips 14, 16 and 18, which are configured for carrying electrical currents circulating respectively between the semiconductor devices 4, 6 and 8 and the other components of the semiconductor package 1. The semiconductor devices 4, 6 and 8 may be connected in parallel.

The semiconductor devices 4, 6 and 8 of FIGS. 3 to 6 produce heat when they are being operated. The thermally conductive layer 2 is configured to dissipate at least part of this heat. The thermally conductive layer 2 may be thermally connected with a heat sink 24 as visible in FIG. 6. Some of the heat produced may be transferred, via the thermally conductive layer 2, from the hotter one(s) of the semiconductor devices 4, 6, 8, herein the central one, to the colder one(s) of the semiconductor devices 4, 6, 8, herein the lateral ones.

The semiconductor package 1 of FIGS. 3 to 6 further comprises a temperature balancing element 20, which may be arranged: in thermal connection with the thermally conductive layer 2 on the one hand, and in thermal connection with each of the semiconductor devices 4, 6, 8 on the other hand, so as to reduce a temperature gradient between the central semiconductor device 6 and the lateral semiconductor devices 4 and 8.

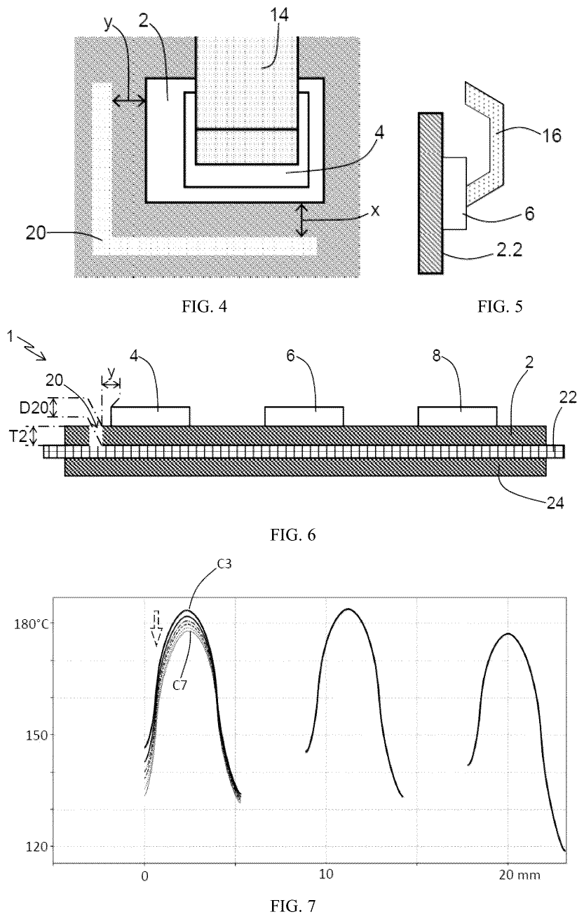

As visible in FIGS. 3 to 4 the temperature balancing element 20 may be arranged in a peripheral region that surrounds the semiconductor devices 4, 6 and 8, for example in the vicinity of dashed line IV shown in FIG. 3. Further, a region 2.1 extending between two neighboring semiconductor devices, e.g. 4 and 6 or 6 and 8, may be free of temperature balancing element, and occupied only by the thermally conductive layer 2. Also, the top face of the thermally conductive layer 2 may comprise at least one extended region 2.2 that is free of semiconductor devices. In the example of FIG. 3 such an extended region 2.2 may extend between the semiconductor device 8 and the edges of the thermally conductive layer 2.

The temperature balancing element 20 may have the shape of an L. The two branches of this L-shape may extend along 100% of the lengths of two outer sides of the semiconductor device 4, respectively. The temperature balancing element 20 may extend around about 50% of the perimeter of the semiconductor device 4.

As shown in FIG. 4, a distance y separating the temperature balancing element 20 from the semiconductor device 4, which is herein the closest one, may be smaller than 25% of the largest dimension of the semiconductor device 4, herein about equal to 10% thereof. As the semiconductor device 4 may substantially have the shape of a rectangle, the largest dimension of the semiconductor device 4 may be the length of a diagonal of this rectangle. In absolute values, the distance y separating the temperature balancing element 20 from the semiconductor device 4 along the direction Y shown in FIG. 3 may be smaller than 0.5 mm.

It appears that, as the temperature balancing element 20 is relatively close to the semiconductor device 4, the temperature balancing element 20 may have a relatively large influence on the thermal resistance locally near the semiconductor device 4.

As shown in FIG. 6, the temperature balancing element 20 may be arranged to locally decrease the thickness T2 of the thermally conductive layer 2 by about 100%, hence through all of the thermally conductive layer 2. In other words, the depth D20 of the temperature balancing element 20 may be about equal to the thickness T2 of the thermally conductive layer 2. The thickness T2 of the thermally conductive layer 2 may for example be decreased by etching the thermally conductive layer 2 at the location of the temperature balancing element 20. The temperature balancing element 20 may be accommodated within the overall shape of the thermally conductive layer 2. For instance, the temperature balancing element 20 does not protrude out of the thermally conductive layer 2.

The thermally conductive layer 2 may be made out of copper and be monolithic. The thermally conductive layer may have a substantially constant thickness of e.g. 0.3 mm at least in the region encompassing the semiconductor devices 4, 6 and 8. For example, the thermally conductive layer 2 may be a DBC substrate.

The temperature balancing element 20 of FIGS. 3 to 6 may include a thermal insulator, which has a lower thermal conductivity than the thermally conductive layer 2. The thermal insulator may have a thermal conductivity of less than 50 W/mK, for example of about 30 W/mK, while the thermally conductive layer 2 may have a thermal conductivity of more than 200 W/mK, for example of about 300 W/mK.

The thermal insulator may be made out of a thermally insulating substance, for example air, in which case the volume of the temperature balancing element 20 may be free from solid materials. Alternatively to air, the volume of the temperature balancing element 20 may be filled with a non-conductive polymer or an insulating packaging material, for example a resin.

As shown in FIG. 6, the semiconductor package 1 may further comprise: i) an electrically insulating layer 22 arranged below the thermally conductive layer 2 and i) the heat sink 24 arranged below the electrically insulating layer 22. In other words, the heat sink 24, the electrically insulating layer 22 and the thermally conductive layer 2 are stacked atop one another.

The electrically insulating layer 22 may have a relatively high thermal conductivity, in order to efficiently transfer heat to the heat sink 24. The electrically insulating layer 22 may for example be made out of a fiber-reinforced plastic or a ceramic material. The heat sink 24 may be configured to help in dissipating away heat produced by semiconductor device 4, 6 and 8. The heat sink 24 may be made out of a thermally conductive material, for example copper or copper alloy.

In a not-shown second embodiment, all or a part (e.g. one branch of an L) of the temperature balancing element may be located further away from the lateral semiconductor device, at least in the direction Y, than the temperature balancing element 20 of FIGS. 3 to 6. In the second embodiment, the distance y separating the lateral branch of temperature balancing element from the semiconductor device may be about as large as the largest dimension of the semiconductor device (diagonal), hence much larger than in the embodiment of FIGS. 3 to 6.

It appears that, when the temperature balancing element is entirely or partly far from the semiconductor device, the temperature balancing element of the second embodiment might have a lesser influence on the thermal resistance near the semiconductor device 4 than the one illustrated in FIGS. 3 to 6.

FIG. 7 illustrates an effect provided by the temperature balancing element 20 to semiconductor packages according to the present disclosure. FIG. 7 is a schematic diagram plotting temperatures (in degrees Celsius) as a function of a position (in mm) along the Y-direction shown in FIG. 3 or 5, in semiconductor devices of various semiconductor packages. For example, the curve C3 may be obtained for the semiconductor device 4 of FIGS. 3 to 6 (first embodiment), while FIG. 7 may be obtained for the not-shown second embodiment. The curves of FIG. 7 may be obtained by computer simulation (e.g. via a finite element simulation software), or by measuring temperatures on actual semiconductor packages.

The curves on the left, center and right parts of FIG. 7 respectively correspond to temperatures obtained for semiconductor packages similar to the ones described above in relation to FIGS. 3-6 and 7. The curves on the left-hand side of FIG. 7 correspond to various semiconductor packages, wherein the distances x and y (in mm) separating the temperature balancing element from the closest semiconductor device vary respectively along the X-direction and along the Y-direction in increasing order as follows:
x=1 and y=6 for the lowest curve C7;
x=1 and y=2;
x=1 and y=1;
x=0.75 and y=0.75;
x=0.5 and y=0.5; and
x=0.25 and y=0.25 for the highest curve C3.

FIG. 7 shows that the closer the temperature balancing elements 20 get to the respective semiconductor devices 4, the hotter these semiconductor devices 4 may become on average and the higher their average or peak temperatures become. Conversely, the farther the temperature balancing elements 20 get from the respective semiconductor devices 4, the colder the semiconductor devices 4 may become on average and the lower their average or peak temperatures become.

The curves in the left part of FIG. 7 illustrate the growing influence that the ever closer temperature balancing element might have on the thermal field in the semiconductor device, not only along the direction Y but over the entire area and volume of the semiconductor device 4 (no isotherm map shown). This is made visible by a comparison between the lowest curve C7 and the highest curve C3, which may represent temperatures obtained for the semiconductor devices 4 of FIGS. 3 to 6 and of the not-shown second embodiment respectively. The temperature balancing element 20 of the semiconductor device 4 may for instance help reducing a temperature gradient between the two semiconductor devices 4 and 6 more or less, for example, as a function of the increasing distance y (the arrow in FIG. 7 shows the sense of increasing values of the distance y).

The effect illustrated in FIG. 7 can be compared with the temperature fields obtained in e.g. the semiconductor package of FIG. 1, where, as shown in FIG. 2, the central semiconductor device 6 becomes substantially hotter than the lateral semiconductor devices 4 and 8 out of which a larger amount of heat can be drained away via the thermally conductive layer 2.

It appears that the thermal insulator forming the temperature balancing element 20 can increase the thermal resistance near the colder semiconductor device 4, so as to increase the average or peak temperature thereof and bring it closer to the average or peak temperatures of the hottest semiconductor device 6 respectively. As temperature gradients between the semiconductor devices 4 and 6 are reduced, the balance of heat produced can be improved in the semiconductor package 1.

The superimposed bell-shaped curves on the right-hand side of FIG. 7 show the temperatures obtained for the semiconductor devices 8 and the likes, which may have no temperature balancing element near them. Accordingly, the thermal field in the semiconductor device 8 might not or not much be influenced by the remote temperature balancing element 20. Hence, these bell-shaped curves may be superimposed.

Likewise, the superimposed bell-shaped curves in the center part of FIG. 7 also show that the thermal field in the semiconductor device 8 might not or not much be influenced by the remote temperature balancing element 20.

The curve on the right part of FIG. 7, where the influence of the temperature balancing element 20 might be negligible, reaches approximately the same temperatures as the lowest curve C7 on the left part of FIG. 7 (second embodiment with a remote temperature balancing element 20). Also, the semiconductor package 1 of FIG. 1, which has no temperature balancing element, would yield a curve lying not far below the lowest curve C7 in the left part of FIG. 7.

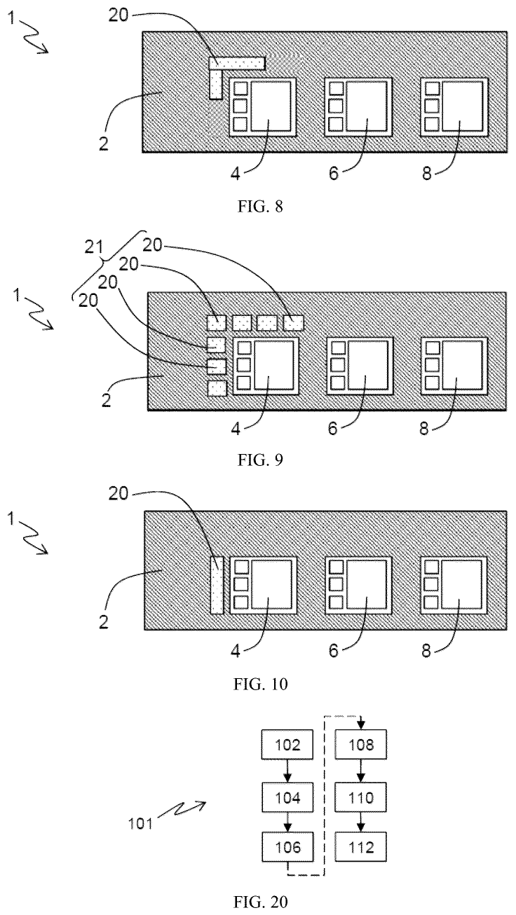

FIGS. 8 to 10 show various embodiments having diverse configurations of temperature balancing elements. The afore-detailed description of FIGS. 3 to 6 may generally be applied to FIGS. 8 to 10, apart at least from the hereinafter-mentioned noticeable differences. An element of semiconductor package 1 of FIGS. 8 to 10 is given the same reference sign as an element having a similar structure or function in FIGS. 3 to 6.

The semiconductor package 1 of FIG. 8 differs from the semiconductor package 1 of FIGS. 3 to 6 in that the L-shaped branches of the temperature balancing element 20 may extend along less than 100%, for example 50%, of the respective lengths of the sides of the lateral semiconductor device 4.

The semiconductor package 1 of FIG. 9 differs from the semiconductor package 1 of FIGS. 3 to 6 in that the semiconductor package may have a group 21 of nearby temperature balancing elements 20. The temperature balancing elements 20 of group 21 may be two by two separated by a gap of e.g. 200 μm formed by the thermally conductive layer 2. The group 21 may generally have the shape of an L, herein with discontinued branches. The two branches of the group 21 may extend along 100% of the sides of the lateral semiconductor device 4.

The semiconductor package 1 of FIG. 10 differs from the semiconductor package 1 of FIGS. 3 to 6 in that the temperature balancing element 20 may be in the form of a straight bar or elongated rectangle, which may extend along 100% of one of the sides of the lateral semiconductor device 4.

In further, non-illustrated embodiments the temperature balancing element may extend along more than or less than 100% of the length of a side of the semiconductor device, for example along 50% or 150% of it.

FIG. 11 is similar to FIG. 6. The afore-detailed description of FIGS. 3 to 6 may be applied to FIG. 11, apart from the hereinafter-mentioned noticeable differences. An element of semiconductor package 1 of FIG. 11 is given the same reference sign as an element having a similar structure or function in FIGS. 3 to 6.

The semiconductor package 1 of FIG. 11 differs from the semiconductor package 1 of FIGS. 3 to 6 in that it may comprise two temperature balancing elements 20.1 and 20.2. The temperature balancing element 20.1 may be arranged between the semiconductor device 4 on the left and a left edge of the thermally conductive layer 2, like the temperature balancing element 20 of FIG. 6, while the temperature balancing element 20.2 may be arranged between the semiconductor device 8 on the right and a right edge of the thermally conductive layer 2.

The temperature balancing element 20.2 may be symmetrical to, and have the same or similar dimensions as, the temperature balancing element 20.1. The temperature balancing element 20.2 may, for instance, have an L-shape extending along two sides of the semiconductor device 8, like in the example of FIGS. 3 to 6. Further, the temperature balancing element 20.2 may be made out of the same insulating substance, for example air.

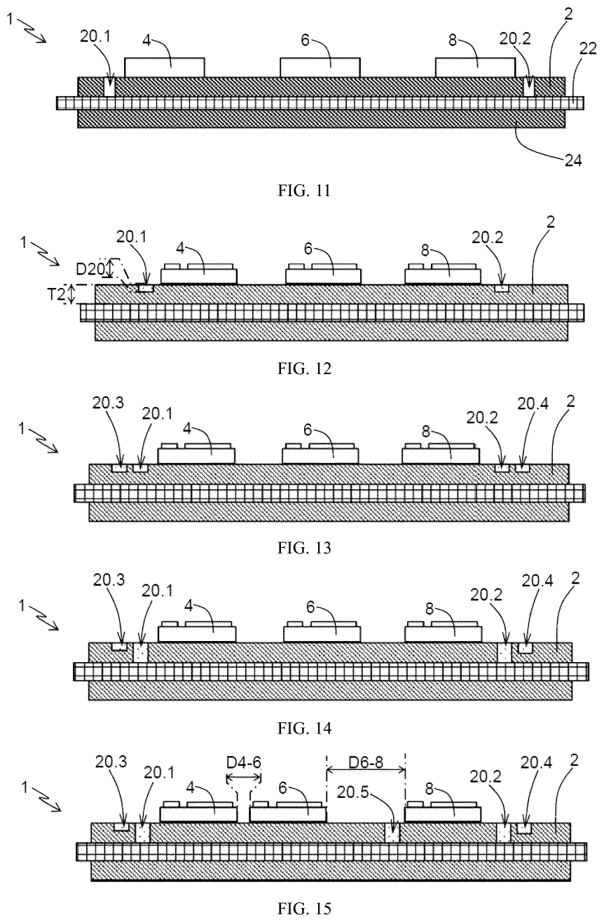

FIG. 12 is similar to FIG. 11. The afore-detailed description of FIG. 11 may be applied to FIG. 12, with similar reference signs assigned to similar structural or functional elements, apart from the hereinafter-mentioned noticeable differences. The semiconductor package 1 of FIG. 12 differs from the semiconductor package 1 of FIG. 11 in that the temperature balancing elements 20.1 and 20.2 may be arranged to locally decrease the thickness, for example after etching, of the thermally conductive layer 2 by about 30% only instead of 100% in FIG. 11.

For example, the depth D20 of the temperature balancing elements 20.1 and 20.2 may be about one third of the depth D20 of the temperature balancing element 20 in FIG. 11, hence about one third of the thickness T2 of the thermally conductive layer 2. The depth D20 may locally influence the thermal resistance around the temperature balancing elements, hence the thermal fields in the nearby semiconductor device(s). The higher the depth D20 may be, the higher the thermal resistance near the respective temperature balancing element 20, 20.1 or 20.2.

FIG. 13 is similar to FIG. 12. The afore-detailed description of FIG. 12 may be applied to FIG. 12, with similar reference signs assigned to similar structural or functional elements, apart from the hereinafter-mentioned noticeable differences. The semiconductor package 1 of FIG. 13 differs from the semiconductor package 1 of FIG. 12 in that it may comprise four temperature balancing elements 20.1, 20.2, 20.3 and 20.4, instead of two in FIG. 12. The additional temperature balancing elements 20.3 and 20.4 may have similar L-shapes as the temperature balancing elements 20.1 and 20.2, respectively. In a not-shown top view similar to FIG. 3, the temperature balancing elements 20.3 and 20.4 may have larger dimensions respectively than the temperature balancing elements 20.1 and 20.2 (homothetic images), and be arranged parallel thereto.

FIG. 14 is similar to FIG. 13. The afore-detailed description of FIG. 13 may be applied to FIG. 14, with similar reference signs assigned to similar structural or functional elements, apart from the hereinafter-mentioned noticeable differences. The semiconductor package 1 of FIG. 14 differs from the semiconductor package 1 of FIG. 13 in that the temperature balancing elements 20.1 and 20.2 may be arranged to locally decrease the thickness of the thermally conductive layer 2 by about 100%, like in the embodiment of FIG. 11, while the temperature balancing elements 20.3 and 20.4 may be arranged to locally decrease the thickness of the thermally conductive layer 2 by about 30%, like in the embodiment of FIG. 13.

FIG. 15 is similar to FIG. 14. The afore-detailed description of FIG. 14 may be applied to FIG. 15, with similar reference signs assigned to similar structural or functional elements, apart from the hereinafter-mentioned noticeable differences.

The semiconductor package 1 of FIG. 14 differs from the semiconductor package 1 of FIG. 13 in that the distance D6-8 separating semiconductor devices 6 and 8 may be larger in the embodiment of FIG. 14 than in the embodiment of FIG. 13. Also, the semiconductor package 1 of FIG. 14 differs from the semiconductor package 1 of FIG. 13 in that the distance D4-6 separating semiconductor devices 4 and 6 may be smaller in the embodiment of FIG. 14 than in the embodiment of FIG. 13. Due to such an offset, the central semiconductor device 6 may be closer to the left semiconductor device 4 than to the right semiconductor device 8.

Besides, each semiconductor device 4, 6 or 8 may further be offset or misaligned with respect to the other semiconductor devices in a plane perpendicular to the plane of FIG. 14, hence in the direction X.

The semiconductor package 1 of FIG. 15 may further differ from the semiconductor package 1 of FIG. 14 in that it may further comprise an additional temperature balancing element 20.5, which is arranged between the semiconductor devices 6 and 8. The additional temperature balancing element 20.5 may be located closer to the lateral semiconductor device 8 than to the central semiconductor device 6. The additional temperature balancing element 20.5 may include a thermal insulator, for example air.

The temperature balancing element 20.5 may have a shape other than the shape of an L. for example, the temperature balancing element 20.5 may have the shape of an elongated rectangle. Nevertheless, the temperature balancing element 20.5 may also substantially have the shape of an L extending on the two opposite sides with respect to the temperature balancing element 20.2.

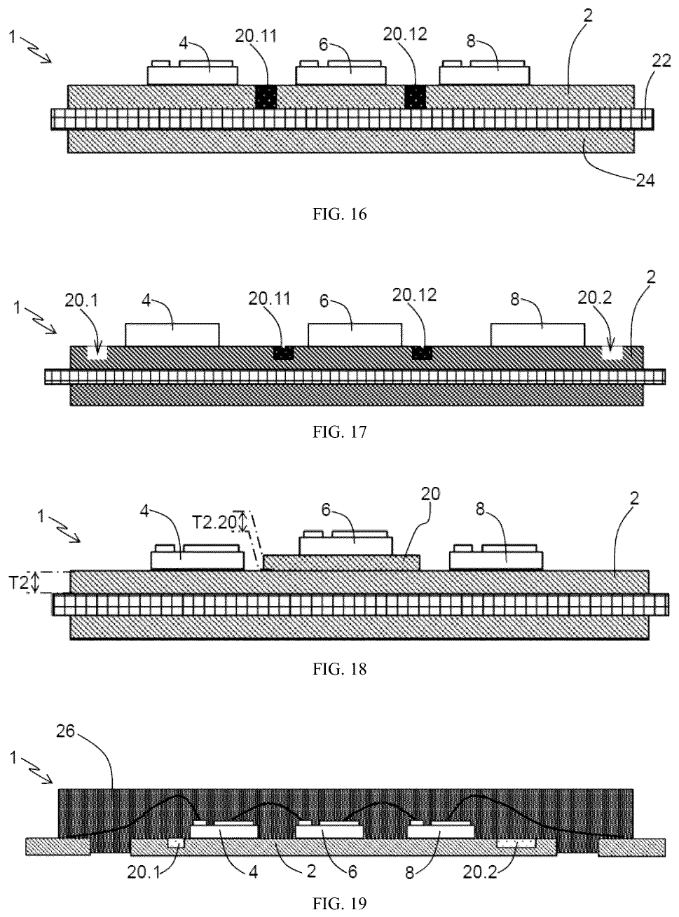

FIG. 16 is similar to FIG. 11. The afore-detailed description of FIG. 11 may be applied to FIG. 16, apart from the hereinafter-mentioned noticeable differences. An element of semiconductor package 1 of FIG. 16 is given the same reference sign as an element having a similar structure or function in FIG. 11.

The semiconductor package 1 of FIG. 16 differs from the semiconductor package 1 of FIG. 11 in that each of the temperature balancing elements 20.11 and 20.12 may include a thermal conductor, which is made out of a thermally conductive material which has a higher thermal conductivity than the thermally conductive layer 2. For example, the thermal conductors may be is made out of copper, while the thermally conductive layer 2 may be made out of aluminum alloy. The thermal conductors may have a thermal conductivity of more than 300 W/mK, while the thermally conductive layer 2 may have a thermal conductivity of less than 300 W/mK.

The semiconductor package 1 of FIG. 16 may further differ from the semiconductor package 1 of FIG. 11 in that the thermal conductor of the temperature balancing element 20.11 may be arranged between the semiconductor devices 4 and 6, while the thermal conductor of the temperature balancing element 20.12 may be arranged between the semiconductor devices 6 and 8.

The semiconductor package 1 of FIG. 16 may further differ from the semiconductor package 1 of FIG. 11 in that the temperature balancing elements 20.11 and 20.12 may substantially have the shape of an elongated rectangle, instead of the shape of an L like in the embodiment of FIG. 11. The temperature balancing elements 20.11 and 20.12 may extend along the entire length of a side of the semiconductor device 6.

Like in the embodiment of FIG. 11, the temperature balancing elements 20.11 and 20.12 of FIG. 16 may be configured to locally decrease the thickness of the thermally conductive layer 2 by about 100%.

In operation, the temperature balancing elements 20.11 and 20.12 can decrease the thermal resistance between the hottest semiconductor device, herein the central one 6, and a neighboring, colder semiconductor device, herein the lateral ones 4 and 8, so as to enhance heat transfer from the hottest semiconductor device 6 toward the colder semiconductor devices 4 and 8.

When considering FIG. 7 the temperature balancing element 20.11 and 20.12 of FIG. 16 would be decreasing the average or peak temperature of the central semiconductor device 6, and bringing such temperature(s) closer to the one(s) in the lateral semiconductor device 4 and 8. As temperature gradients between the semiconductor devices 4, 6 and 8 can be reduced, the balance of heat can be improved in the semiconductor package 1.

FIG. 17 is similar to FIG. 16. The afore-detailed description of FIG. 16 may be applied to FIG. 17, apart from the hereinafter-mentioned noticeable differences. An element of semiconductor package 1 of FIG. 17 is given the same reference sign as an element having a similar structure or function in FIG. 16.

The semiconductor package 1 of FIG. 17 differs from the semiconductor package 1 of FIG. 16 in that, in addition to comprising two temperature balancing elements 20.11 and 20.12 including thermal conductors like in the embodiment of FIG. 16, it may further comprise two temperature balancing elements 20.1 and 20.2 including thermal insulators like in the embodiment of FIG. 12.

In operation, the semiconductor package 1 can cumulate the effect of the temperature balancing elements 20.11 and 20.12, which may include thermal conductors and may decrease the thermal resistance locally, with the effect of the temperature balancing elements 20.1 and 20.2, which may include thermal insulator and may increase the thermal resistance locally. Each of these effects can tend to balance the heat and the thermal fields among the semiconductor device 4, 6 and 8, hence in the semiconductor package 1.

FIG. 18 is similar to FIG. 16. The afore-detailed description of FIG. 16 may be applied to FIG. 18, with similar reference signs assigned to similar structural or functional elements, apart from the hereinafter-mentioned noticeable differences.

The semiconductor package 1 of FIG. 18 differs from the semiconductor package 1 of FIG. 16 in that the semiconductor package 1 may comprise only one temperature balancing element 20, instead of two like in the embodiment of FIG. 16.

Like in the embodiment of FIG. 16, the thermal conductor of FIG. 18 may be included in a temperature balancing element 20 arranged between two semiconductor devices 6 and 4 or 6 and 8.

Unlike the thermal conductors of FIG. 16 where thermal conductors are arranged on each side of the central semiconductor device 6, the thermal conductor of FIG. 18 may include a thermal interface which is arranged between the thermally conductive layer 2 and the semiconductor device 6.

The semiconductor package 1 of FIG. 18 may further differ from the semiconductor package 1 of FIG. 16 in that the thermal interface forming the thermal conductor extends over and beyond the lower face of the semiconductor device 6. The temperature balancing element 20 may extend underneath the semiconductor device 6. The thermal interface may have the shape of a plate of a slightly larger size than the lower face of the semiconductor device 6.

The thermal interface may be formed by a local increase T2.20 of the thickness T2 of the thermally conductive layer 2. This thermal interface can represent an additional thermally conducting layer under the semiconductor device 6. The thermal interface may locally increase the thickness of the thermally conductive layer by 75%.

The semiconductor package 1 of FIG. 18 may further differ from the semiconductor package 1 of FIG. 16 in that the thermal interface may be made out of the same material as the thermally conductive layer 2, whereas the thermal conductors of the embodiment of FIG. 16 may be made of a material that has a higher thermal conductivity than the thermally conductive layer 2. The thermal interface of FIG. 18 may be integral with the thermally conductive layer 2.

In operation, the temperature balancing element 20 can largely decrease the thermal resistance between the hottest semiconductor device 6 and the neighboring, colder semiconductor devices 4 and 8, so as to enhance heat transfer from the hottest semiconductor device 6 toward the colder semiconductor devices 4 and 8.

FIG. 19 is similar to FIG. 12. The afore-detailed description of FIG. 12 may be applied to FIG. 19, with similar reference signs assigned to similar structural or functional elements, apart from the hereinafter-mentioned noticeable differences.

The semiconductor devices 4, 6 and 8 of FIG. 19 may be embedded in a mold compound 26. The semiconductor package 1 of FIG. 19 differs from the semiconductor package 1 of FIG. 12 in that the semiconductor package 1 may formed by devices mounted on a lead-frame, like for example a multi-chip package, while the semiconductor package 1 of FIG. 12 is a power module mounted on a DBC substrate. In further not-shown implementations, the semiconductor package 1 may be an insulated metal substrate (IMS), a power PCB assembly etc.

FIG. 20 illustrates a method 101, according to a second embodiment of the present disclosure, for manufacturing a semiconductor package according to the afore-detailed embodiments. The manufacturing method 101 comprises: a step 108 of providing a thermally conductive layer, a step 110 providing at least two semiconductor devices, and a step 112 of arranging said at least two semiconductor devices in thermal connection with the thermally conductive layer, the at least two semiconductor devices producing heat when being operated; wherein the thermally conductive layer is configured to dissipate at least a part of the heat produced by the at least two semiconductor devices; wherein some of said heat being transferred at least from one of the at least two semiconductor devices to another one of the at least two semiconductor devices; and wherein the semiconductor package has at least one temperature balancing element, the at least one temperature balancing element being arranged in thermal connection i) with the thermally conductive layer and ii) with at least one of the at least two semiconductor devices so as to reduce a temperature gradient between two neighboring semiconductor devices of the at least two semiconductor devices.

The manufacturing method 101 makes it possible to manufacture a semiconductor package according to the present disclosure.

The manufacturing method 101 may initially comprise a step 102 of implementing a model of the semiconductor package on a computer, for example via a software. Further, the method 101 may comprise a step 104 of inputting a set of operating conditions in the computer, for example via a software, and a step 106 of processing, with the computer and possibly a software, a simulation of the thermal field in the semiconductor devices as a function of said set of operating conditions.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation. Also, the various implementation forms and examples described in the present disclosure may be combined, when technically feasible, to define additional implementation forms which are also part of this disclosure.

What is claimed is:

1. A semiconductor package comprising:
semiconductor devices configured to produce heat during operation;
a thermally-conductive layer in thermal connection with the semiconductor devices and configured to dissipate at least a part of the heat; and
a first temperature-balancing element arranged in thermal connection with the thermally-conductive layer and at least one of the semiconductor devices and configured to reduce a temperature gradient between the semiconductor devices,
wherein the first temperature-balancing element has a shape that is substantially a rectangle, an L, an arc of a circle, or an arc of an ellipse.

2. The semiconductor package of claim 1, wherein the first temperature-balancing element is further configured to locally decrease a thickness of the thermally-conductive layer.

3. The semiconductor package of claim 1, wherein the first temperature-balancing element is further configured to locally decrease a thickness of the thermally-conductive layer by 5-100%.

4. The semiconductor package of claim 1, wherein the first temperature-balancing element comprises a thermal insulator having a lower thermal conductivity than the thermally-conductive layer.

5. The semiconductor package of claim 4, wherein the thermal insulator is arranged in a peripheral region surrounding the semiconductor devices.

6. The semiconductor package of claim 1, wherein the first temperature-balancing element comprises a thermal conductor having a higher thermal conductivity than the thermally-conductive layer, and wherein the thermal conductor is arranged between the semiconductor devices.

7. The semiconductor package of claim 6, wherein the thermal conductor comprises gold, a gold alloy, copper, or a first copper alloy, and wherein the thermally-conductive layer comprises aluminum, an aluminum alloy, copper, or a second copper alloy.

8. The semiconductor package of claim 6, wherein the thermal conductor comprises a thermal interface arranged between the thermally-conductive layer and one of the semiconductor devices, and wherein the thermal interface extends over an entire area of the semiconductor devices.

9. The semiconductor package of claim 8, wherein the thermal interface comprises a same material as the thermally-conductive layer, and wherein the thermal interface is integrated with the thermally-conductive layer.

10. The semiconductor package of claim 8, wherein the thermal interface is configured to locally increase a thickness of the thermally-conductive layer by 30%-200% or 50-100%.

11. The semiconductor package of claim 1, wherein the thermally-conductive layer comprises a substantially-constant thickness in a region encompassing the semiconductor devices.

12. The semiconductor package of claim 1, wherein a distance separating the first temperature-balancing element from a closest one of the semiconductor devices is smaller than 25-300 of a largest dimension of the closest one of the semiconductor devices.

13. The semiconductor package of claim 1, wherein the first temperature-balancing element extends on a side of a closest one of the semiconductor devices and along 50%-150 of a length of the one side.

14. The semiconductor package of claim 13, wherein the first temperature-balancing element extends on sides of the closest one of the semiconductor devices and along 50-150 of respective lengths of the sides.

15. The semiconductor package of claim 1, wherein the thermally-conductive layer comprises an outer face, and wherein the outer face comprises an extended region free of the semiconductor devices.

16. The semiconductor package of claim 1, further comprising a second temperature-balancing arranged proximate to the first temperature-balancing element.

17. The semiconductor package of claim 1, wherein the semiconductor devices are arranged in an array, and comprise three semiconductor devices.

18. The semiconductor package of claim 1, further comprising an electrically-insulating layer, wherein the semiconductor package (1) is a power module, wherein the semiconductor devices are insulated-gate bipolar transistors (IGBTs), and wherein the semiconductor devices are embedded in the electrically-insulating layer.

19. A semiconductor package comprising:
semiconductor devices configured to produce heat during operation;
a thermally-conductive layer in thermal connection with the semiconductor devices and configured to dissipate at least a part of the heat, wherein the thermally-conductive layer comprises aluminum, an aluminum alloy, copper, or a first copper alloy; and
a temperature-balancing element arranged in thermal connection with the thermally-conductive layer and at least one of the semiconductor devices, configured to reduce a temperature gradient between the semiconductor devices, and comprising a thermal conductor having a higher thermal conductivity than the thermally-conductive layer,
wherein the thermal conductor is arranged between the semiconductor devices, and
wherein the thermal conductor comprises gold, a gold alloy, copper, or a second copper alloy.

20. A method for manufacturing a semiconductor package and comprising:
providing a thermally-conductive layer;
providing semiconductor devices;
arranging the semiconductor devices in thermal connection with the thermally-conductive layer; and
arranging a temperature-balancing element to be in contact with the thermally-conductive layer and in thermal connection with the semiconductor devices to reduce a temperature gradient between the semiconductor devices,
wherein the temperature-balancing element has a shape that is substantially a rectangle, an L, an arc of a circle, or an arc of an ellipse.
